(19) United States
(12) Patent Application Publication
(10) Pub. No.: US 2025/0211107 A1
(43) Pub. Date: Jun. 26, 2025

(54) AUTONOMOUS SOFT/HARD SWITCHING TRANSITION OF SWITCHING CONVERTERS TO IMPROVE LIGHT LOAD EFFICIENCY

(71) Applicant: Intel Corporation, Santa Clara, CA (US)

(72) Inventors: Avinash Shreepathi Bhat, Vancouver, WA (US); Christopher Schaef, San Diego, CA (US)

(21) Appl. No.: 18/394,955

(22) Filed: Dec. 22, 2023

(51) Int. Cl. H02M 3/157; H02M 1/088; H03K 17/06; H03K 17/687

(52) U.S. Cl. CPC H02M 3/157; H02M 1/088; H03K 17/063; H03K 17/687; H03K 2217/0063; H03K 2217/0072

(57) ABSTRACT

Embodiments herein relate to a switching power converter which monitors the output voltage of a power train as it varies between peaks and valleys during switching of the power train. The power train includes a high-side p-type transistor and a low-side n-type transistor. When a peak of the output voltage is positive for a number of consecutive clock cycles, a process is initiated to transition the high-side transistor from hard switching to soft switching. This involve gradually increasing a time between a turn off of the low-side transistor and a turn on of the high-side transistor. The switching power converter can include a comparator and logic circuits.

### BACKGROUND

Computing devices often rely on power converters to obtain power. A power converter is an electrical circuit which accepts a direct current (DC) input and generates a DC output of a different voltage, usually achieved by high frequency switching of inductive and/or capacitive elements. For example, a power converter can convert the main supply voltage of a computing device, such as 12-48 V, down to lower voltages, such as about 1 V. The lower voltages can be used by various components in the computing device, such as a Universal Serial Bus (USB) interface, memory such as dynamic random access memory (DRAM) and processing resources such as a central processing unit (CPU). However, it is challenging to supply power in an efficient manner.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts an example switching power converter 100 including a first power switch PS1 and a second power switch PS2 in a power train 110, where a control circuit 120 can transition PS1 from hard switching to soft switching at light loads by monitoring an output voltage Vx of the power train, in accordance with various embodiments.

FIG. 2 depicts an example plot of VR efficiency versus load current output using hard switching and soft switching, in accordance with various embodiments.

FIG. 3 depicts example waveforms for the power converter 100 of FIG. 1, illustrating a time period tdp-tdn which can be adjusted to provide hard switching or soft switching, in accordance with various embodiments.

FIG. 4A depicts a flowchart of an example process for detecting a light load to determine when to transition PS1 from hard switching to soft switching, in accordance with various embodiments.

FIG. 4B depicts a flowchart of an example process for implementing operation 405 of FIG. 4A for gradually transitioning PS1 from hard switching to soft switching, in accordance with various embodiments.

FIG. 5 depicts example plots showing a gradual transition from hard switching to soft switching consistent with FIG. 4B, in accordance with various embodiments.

FIG. 6 depicts an example block diagram implementation of the control circuit 120 of FIG. 1, in accordance with various embodiments.

FIG. 7 depicts an example implementation of the switching logic circuit 620 of FIG. 6, in accordance with various embodiments.

FIG. 8 depicts example waveforms consistent with implementation of the switching logic in FIG. 7, in accordance with various embodiments.

FIG. 9A depicts an example implementation of the comparator 710 of FIG. 7, in accordance with various embodiments.

FIG. 9B depicts an example implementation of the multiplexer 990 of FIG. 9A, in accordance with various embodiments.

FIG. 10 depicts example plots consistent with the implementation of the comparator 710 in FIG. 9A, in accordance with various embodiments.

FIG. 11 illustrates an example of components that may be present in a computing system 1150 for implementing the techniques (e.g., operations, processes, methods, and methodologies) described herein.

### DETAILED DESCRIPTION

As mentioned at the outset, various challenges are presented in operating a power converter.

A switching power converter can include a first power switch such as a p-type transistor in a series with a second power switch such as an n-type transistor, where the transistors are alternately turned on and off to provide power at an output node between the switches. The switches may be controlled by respective pulse width modulation (PWM) signals, for example. The first power switch is also referred to as a high-side switch as it is coupled to a power supply while the second power switch is also referred to as a low-side switch as it is coupled to ground. However, such power converters can suffer from higher power consumption and therefore reduced efficiency at moderate to low utilization. One of the contributors to higher power consumption at low utilization are voltage regulator (VR) switching losses which are the dominant VR loss mechanism at low loads.

One approach is to use soft switching to reduce switching losses at low loads. Soft switching refers to providing a relatively large time margin between turning off one switch and turning on the other switch. A goal is to turn on a switch when there is 0 V across it to avoid capacitive losses. However, utilizing soft switching settings can lead to significant efficiency loss at moderate and high currents. On most domains, power management circuits are unable to accurately predict the current and configure the soft/hard switching. Hence, only hard switching settings may be used, leading to poor light-load efficiency. Another issue is that a voltage droop or other perturbation can occur in the output voltage if there is an abrupt transition to the soft switching mode.

One approach is to use data from load current sensing circuitry to detect a set current level to enable a mode transition. However, autonomous transition techniques have not been implemented in high-speed, high voltage switching converters like fully-integrated voltage regulators (FIVRs). Moreover, the inaccuracy of current sensing and the variability of the current level to be set for mode transition, with respect to supply voltage, output voltage and inductor value, can result in an inefficient and unreliable implementation.

The solutions provided herein address the above and other disadvantages. In one aspect, a VR includes a high-speed, high-precision comparator which observes the drain voltage of the low-side power switch during each switching cycle to detect negative inductor current. This detection then enables soft switching of the high-side power switch. In particular, detection of the negative current can trigger a slow and gradual entry into soft switching mode to ensure a stable response. On the other hand, when a higher load current is present, it is immediately detected, and hard switching is enabled to guarantee reliability of the power switches. These and other features will be further apparent in view of the following discussion.

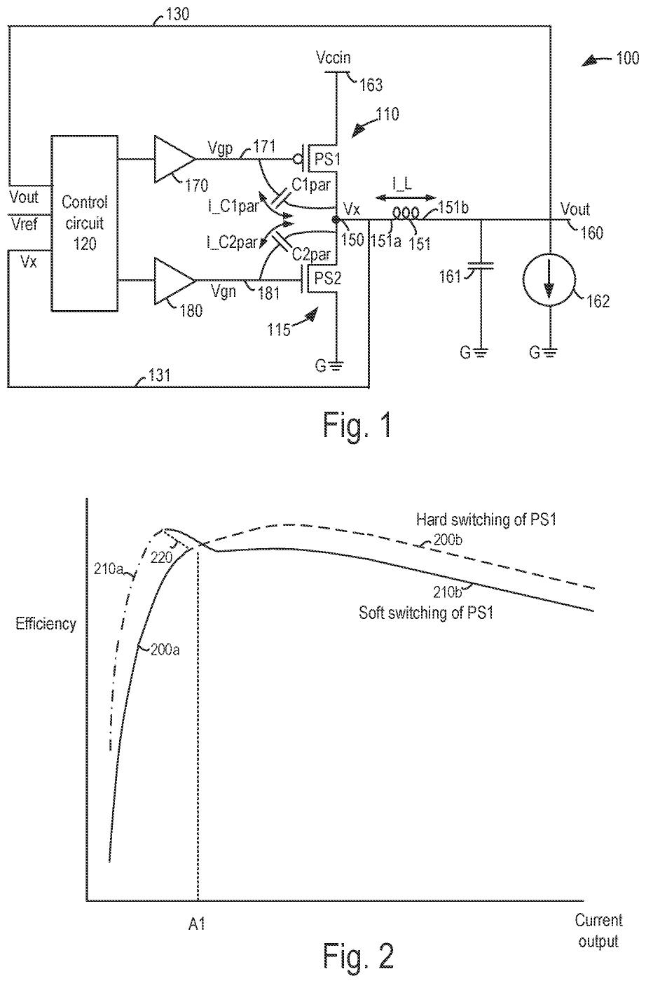

FIG. 1 depicts an example switching power converter 100 including a first power switch PS1 and a second power switch PS2 in a power train 110, where a control circuit 120 can transition PS1 from hard switching to soft switching at light loads by monitoring an output voltage Vx of the power train, in accordance with various embodiments. As mentioned, a switching power converter can include first and second power switches, PS1 and PS2, respectively, in a power train 115. A voltage Vx is provided at an output node 150 of the power train which is between PS1 and PS2. The output node is coupled to a first end 151a of an inductor 151, and a second end 151b of the inductor is coupled to an output node 160 of the VR. An output capacitor 161 and a load current 162 are coupled to the output node 160. PS1 has a source coupled to a power supply terminal 163 at a power supply voltage Vcc while PS2 has a source coupled to ground (G). The drains of PS1 and PS2 are coupled to one another at the node 150.

Each power switch can be driven by a respective driver. For example, PS1 receives a control gate voltage Vgp on a path 171 from a driver 170, and PS21 receives a control gate voltage Vgn on a path 181 from a driver 180. PS1 may be a p-type transistor such as a p-type metal-oxide-semiconductor field-effect transistor (MOSFET) and PS2 may be an n-type transistor such as an n-type MOSFET. The drivers provide the control gate voltages based on signals received from a control circuit 120. The control circuit receives, as inputs, Vout from the VR output node 160 via a feedback path 130, a reference voltage Vref, which is a set point or requested output voltage of the VR, and the power train output voltage Vx via a feedback path 131.

In operation, the power switches have parasitic capacitances which can result in a current flow as indicated by the curved arrows. For example, PS1 has a parasitic capacitance C1par and a current I_C1par between path 171 and node 150, and PS2 has a parasitic capacitance C2par and a current I_C2par between path 181 and node 150. When PS1 is on and PS2 is off, the power supply is coupled to the node 150 so that Vx is approximately equal to Vcc. When PS1 and PS2 are turned on and off, energy is stored in, and released from, the inductor. Additionally, the parasitic capacitances are charged and discharged.

In particular, when current I_L flows to the right, referring to the arrow near the inductor, the parasitic capacitances are discharged, resulting in a decrease in Vx. With hard switching of PS2, PS2 is turned on hard as soon as PS1 is turned off, and the parasitic capacitances are discharged into the ground node. With soft switching, when PS1 is turned off, there is a period in which both PS1 and PS2 are off. In this period, the parasitic capacitances discharge into the output node 160 at Vout through the inductor peak current. Vx continues to fall and PS2 is turned on when Vx reaches approximately 0 V. This approach results in better efficiency compared to hard switching. In one approach, PS2 is always soft switching in the VR since, most of the time, the VR load current is expected to be positive, resulting in a positive inductor peak current which causes Vx to fall. Although, hard switching of PS2 could be configured if desired.

When current flows to the left, the parasitic capacitances are charged, resulting in an increase in Vx. With hard switching of PS2, when load current is high enough that I_L is positive when PS2 is turned off, PS1 needs to be turned on as soon as PS2 is turned off to avoid a large negative value of Vx. Current from Vcc will charge the parasitic capacitances. With soft switching, when the load current is low enough that I_L is negative when PS2 is turned off, the parasitic capacitances can charge through the negative inductor current as Vx rises. PS1 is turned on as Vx reaches approximately Vcc. For best overall efficiency, hard switching of PS1 can be used for higher loads and soft switching can be used for PS1 when the load is low enough to generate a negative I_L and a corresponding positive Vx.

FIG. 2 depicts an example plot of VR efficiency versus load current output using hard switching and soft switching, in accordance with various embodiments. The plots 200a and 200b represent the VR efficiency with hard switching of PS1 and the plots 210a and 210b represent the VR efficiency with soft switching of PS1. Soft switching is used for PS2 is both cases. Generally, soft switching is more efficient at low output currents such as below a level A1, and hard switching is more efficient at high output currents such as above A1. The solutions provided herein provide a gradual transition from hard switching to soft switching as represented by the plot 220 to obtain the highest possible efficiency at both high and low currents.

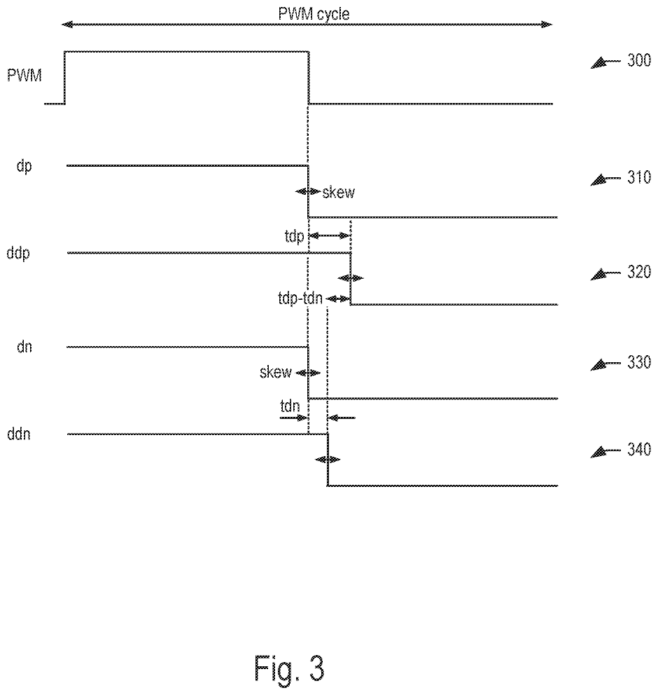

FIG. 3 depicts example waveforms for the power converter 100 of FIG. 1, illustrating a time period tdp-tdn which can be adjusted to provide hard switching or soft switching, in accordance with various embodiments. The control circuit 120 can provide consecutive cycles of a PWM signal as represented by the single cycle of the plot 300. The PWM signal is high and then low. The portion of the cycle in which the signal is high is the duty cycle. Additionally, the control circuit can include delay circuitry. For example, for PS1, the control circuit can provide the signal dp (plot 310) which is time-aligned with the PWM signal, and ddp (plot 320), which is delayed relative to dp by an amount tdp. The signals can also have a skew as indicated which refers to the fact that the same signal can arrive at different components at different times due to gate or propagation delays, for example.

The control circuit can also provide the signal dn (plot 330) which is time-aligned with the PWM signal, and ddn (plot 340), which is delayed relative to dn by an amount tdn. The time period tdp-tdn is also depicted. This represents a time period between turning off PS2 and turning on PS1. For hard switching, this time period will be very short, e.g., 0-50 ps. For soft switching, this time period will be longer, e.g., 1 ns, which is 20×50 ps. In one approach, this time period is at least ten times (a factor of ten) greater for soft versus hard switching.

The signals can be provided from the control circuit to the drivers to provide the control gate voltages used to drive PS1 and PS2. For example, the driver 170 (FIG. 1) may use ddp to provide Vgp to drive PS1, and the driver 180 may use ddn to provide Vgn to drive PS2. Vgp and Vgn are switching signals for PS1 and PS2, respectively.

The PWM signal can be inverted to generate dp and dn. ddp is generated by adding the delay tdp to dp. The dp and ddp signals are level-shifted up used to generate Vgp, the signal that drives PS1. Also, dn is level-shifted down to generate Vgn, the signal that drives PS2.

Note that the PWM signal can be inverted relative to the plot 300. In this case, when PWM is low, dp will be high initially and then when PWM goes high, dp goes low.

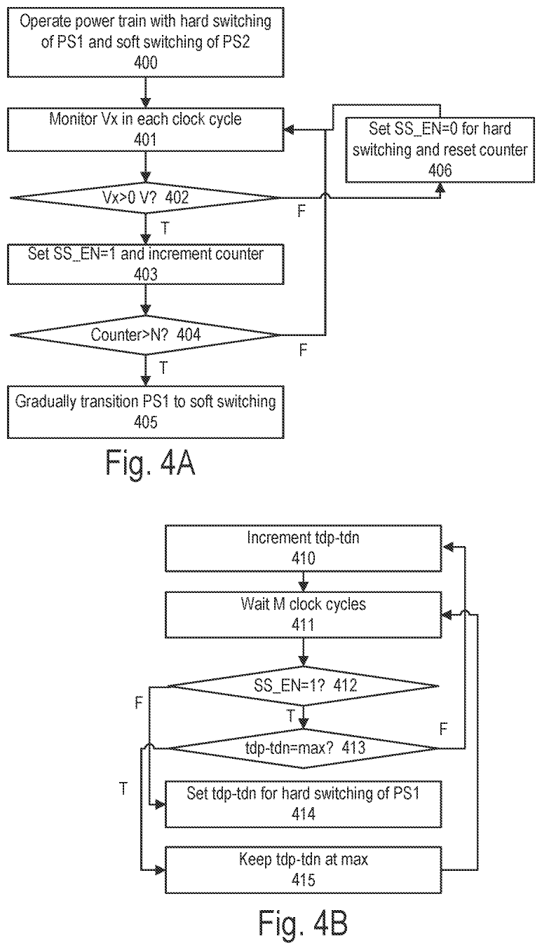

FIG. 4A depicts a flowchart of an example process for detecting a light load to determine when to transition PS1 from hard switching to soft switching, in accordance with various embodiments. Operation 400 includes operating the power train with hard switching of PS1 and soft switching of PS2. Operation 401 includes monitoring Vx in each clock cycle, e.g., of a clock of a control circuit of the VR. A decision operation 402 determines whether Vx>0 V (or other reference voltage close to 0 V). If the decision operation 402 is true (T), operation 403 is reached, which sets a soft switching enable signal SS_EN=1 and increments a counter. If the decision operation 402 is false (F), operation 406 is reached, which sets SS_EN=0 to provide hard switching and resets the counter. Operation 401 is then repeated to monitor Vx again in the next clock cycle.

A decision operation 404 determines whether the counter>N, where N is a configurable number of consecutive clock cycles in which SS_EN=1 before a transition to soft switching can be initiated for PS1. In an example implementation, N=64. The VR can operate more reliably by ensuring SS_EN=1 (and thus Vx>0 V) for several consecutive clock cycles before initiating a transition to soft switching for PS1. If the decision operation 404 is true, operation 405 is reached, which gradually transitions PS1 to soft switching, such as depicted in FIG. 4B. If the decision operation 404 is false, operation 401 is then repeated to monitor Vx again in the next clock cycle.

FIG. 4B depicts a flowchart of an example process for implementing operation 405 of FIG. 4A for gradually transitioning PS1 from hard switching to soft switching, in accordance with various embodiments. In an example approach, the transition involves incrementing tdp-tdn in steps. This helps ensure a reliable operation as opposed to suddenly transitioning from hard to soft switching. As mentioned, this is the time period between the turn off of PS2 and the turn on of PS1 and results in hard or soft switching when it is relatively small or large, respectively.

Operation 410 includes incrementing tdp-tdn. Operation 411 involves waiting M clock cycles. M is a configurable number which represents the step duration. As an example M=4 clock cycles. Generally, M<N and N/M is the number of steps of tdp-tdn before it reaches a maximum allowable value (max). M can be >1, for example. Increasing tdp-tdn in steps can improve the large signal stability of the VR control loop.

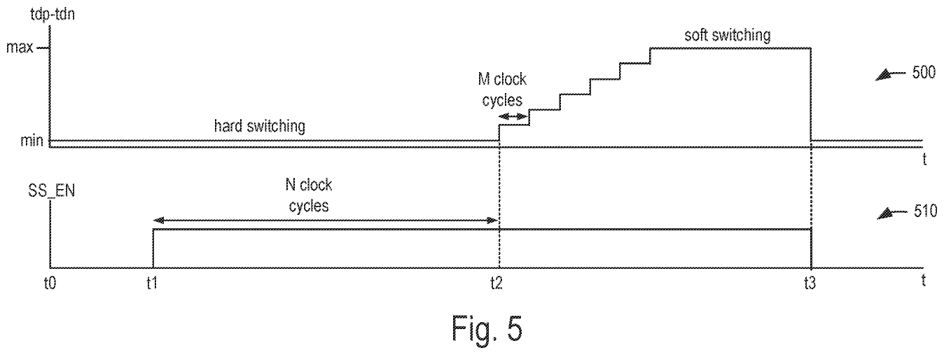

A decision operation 412 determines if SS_EN=1. The operation of FIG. 4B can be concurrent with the operation of FIG. 4A such that Vx continues to be evaluated and SS_EN is set correspondingly in each clock cycle. If Vx is no longer >0 V, such that SS_EN=0, the decision operation 412 is false and operation 414 is reached. Operation 414 involves setting tdp-tdn for hard switching of PS1 and aborting the transition to soft switching. If decision operation 412 is true, a decision operation 413 determines whether tdp-tdn=max. If the decision operation 413 is true, operation 415 is reached, where tdp-tdn is kept at the max value. Operations 411 and 412 then follow in case it is necessary to return to hard switching when SS_EN changes from 1 to 0, for example. If the decision operation 413 is false, operation 410 is reached, where the next increment or step in the transition is initiated. See also FIG. 5. Operation 411 also follows operation 415.

In this example, each step up in tdp-tdn has the same amplitude and duration so that tdp-tdn increased linearly toward a maximum value. However, other approaches are possible. For example, the transition could be non-linear, where different step amplitudes and/or durations are used.

FIG. 5 depicts example plots showing a gradual transition from hard switching to soft switching consistent with FIG. 4B, in accordance with various embodiments. A plot 500 depicts tdp-tdn versus time over an example time period which includes time points t0-t3. tdp-tdn varies between minimum (min) and maximum (max) levels which represent hard and soft switching, respectively. A plot 510 depicts SS_EN which, as discussed=1 when Vx>0 V, indicating that the VR has a light load so that soft switching is appropriate. At t0-t1, SS_EN=0, so that tdp-tdn is set to the min value for hard switching. At t1, SS_EN changes from 0 to 1. However, this is not sufficient to trigger a transition to soft switching because SS_EN must=1 for N consecutive clock cycles, as mentioned, in one possible implementation. From t1-t2, SS_EN=1 for N consecutive clock cycles so that, at t2, a transition to soft switching is initiated. tdp-tdn is incremented by one step at t2, where the step duration is M clock cycle. As long as SS_EN=1, tdp-tdn is stepped up until it reaches the max level, where it remains until t3, when SS_EN changes to 0. As a result, hard switching of PS1 is used after t3. As mentioned, if SS_EN changes to 0 during the step up of tdp-tdn, the step up is terminated and the switching mode is immediately returned to hard switching.

The clock cycles after t2 are subsequent clock cycles after the N consecutive clock cycles.

Note that FIGS. 4A, 4B and 5 refer to tdp-tdn as changing. In an example implementation, when the autonomous soft switching is only performed on the high side p-type MOSFET, tdp alone is the parameter undergoing all the changes and tdn is set to 0.

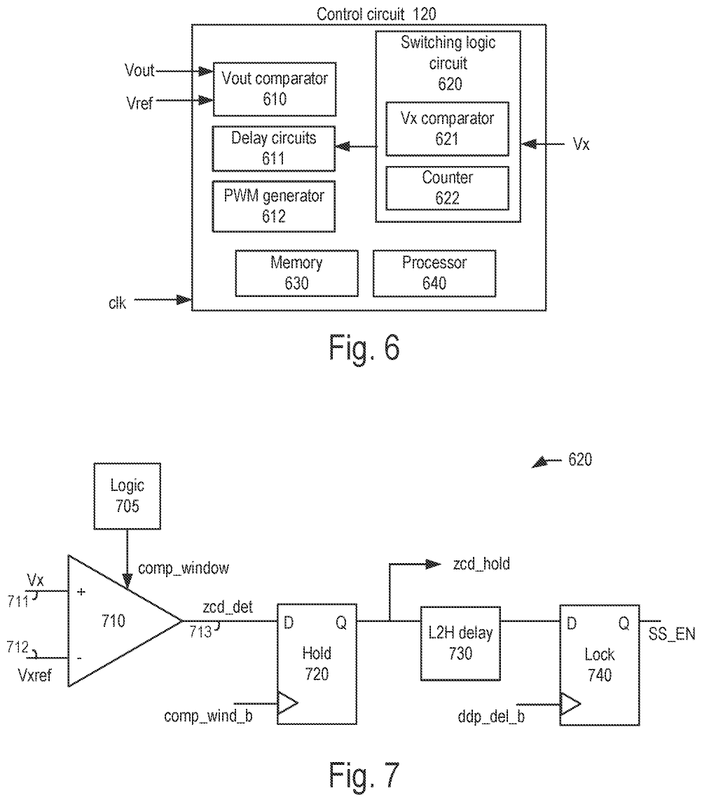

FIG. 6 depicts an example block diagram implementation of the control circuit 120 of FIG. 1, in accordance with various embodiments. The control circuit can be implemented in hardware and/or software. The control circuit may include a memory 630 to store instructions and a processor 640 to execute the instructions to provide the features described herein. The control circuit may include a Vout comparator 610, which compares Vout, the output voltage of the VR, with a reference voltage or set point, Vref. Based on the comparison, a PWM generator 612 can adjust a duty cycle of a PWM signal (FIG. 3) which is used to drive the power switches. Delay circuits 611 can be used to insert delays into the PWM signals such as to provide the signals ddp and ddn, as discussed in connection with FIG. 3. A delay circuit can include digital components, such as shift registers or digital delay lines, to introduce a delay.

A switching logic circuit 620 can determine whether to use soft or hard switching, and when to start a gradual transition from hard to soft switching. The switching logic circuit can be an electronic circuit that performs a logical operation on one or more binary inputs to produce a binary output. In other words, it processes digital signals (typically represented by 0s and 1s) based on predefined logical rules. The basic building blocks of logic circuits are logic gates. These gates perform basic logical operations such as AND, OR, NOT, NAND, NOR, XOR, etc. Each gate takes one or more binary inputs and produces a binary output based on the specific logic function it performs. Logic circuits can include combinational and sequential logic circuits. Combinational logic circuits generate outputs solely based on their current inputs, while sequential logic circuits have memory elements (like flip-flops) that allow them to store information about past inputs and outputs. Based on inputs such as Vx, the switching logic circuit 620 provides an output to the delay circuits 611.

The switching logic circuit 620 can include a Vx comparator 621, which compares Vx to a reference voltage Vxref such as 0 V. A counter 622 can be used to count the number of consecutive clock cycles in which Vx>Vxref. This can be the number of consecutive clock cycles in which SS_EN=1, for example. The counter can increment by one for each consecutive clock cycle in which SS_EN=1.

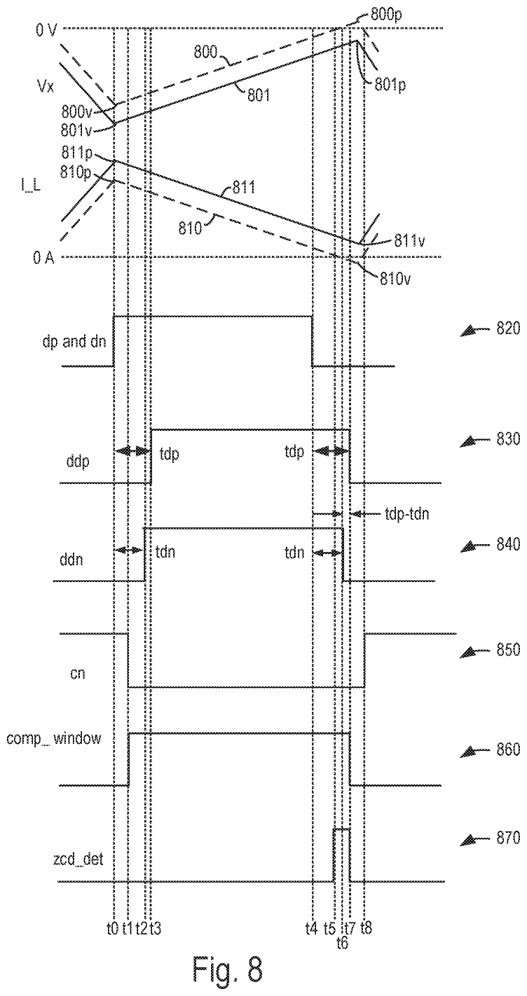

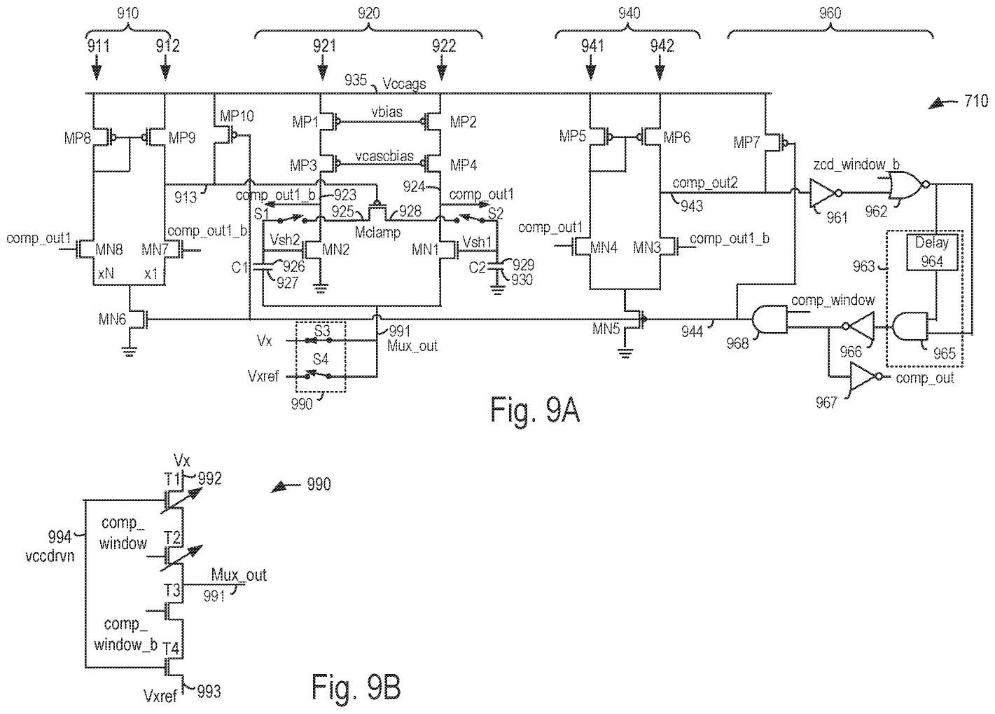

FIG. 7 depicts an example implementation of the switching logic circuit 620 of FIG. 6, in accordance with various embodiments. The switching logic includes logic 705 which provides a value comp_window to a comparator 710. Comp_window, or comparison window, indicates a time in which a comparison can be made between Vx and Vxref. The comparator window is a clock generated such that when the signal goes low when PS1 (the high-side pFET) is on, the comparator is auto-zero/calibrated (see also FIGS. 8 and 9A). When PS2 (the low-side nFET) is on, this signal goes high, and the comparator is in a sense/comparison mode. Vx is on a non-inverting input path 711 of the comparator, and Vxref is on an inverting input path 712 of the comparator. Based on the comparison, the comparator provides an output zed_det on an output path 713. When Vx>Vxref, zcd_det goes high, e.g., 1. zcd_det is input to the data input Q of a flip-flop circuit (flip-flop) 720 such as a D-type flip-flop.

The D-type flip-flop includes a data (D) input, a clock input (shown by a triangle), which receives a clock signal com_wind_b, and a data output Q. The flip-flop has two stable states and can store one bit of state information. When the clock is low, Q=0 regardless of D and when the clock is high, Q=0 or 1 if D=0 or 1, respectively. The flip-flop may be triggered by a positive edge of the clock, for example. The flip-flop 720 acts to hold the value zcd_det. An output of the flip-flop 720 at Q is the value zcd_hold. This value can be output for further processing by the switching logic. This value is also input to a low-to-high (L2H) delay circuit 730 which imposes a delay before provided the value as data D to a flip-flop 740, which locks the value. The delay circuit adds a delay to the rising edge (low to high) of the digital signal. The flip-flop 740 outputs a soft switching enable signal, SS_EN, at Q, at a time set by a clock signal ddp_del_b. ddp_delay is a clock generated to synchronize the final signal, SS_EN, that enables soft switching. ddp_del corresponds to tdp=tdpss_max+delta. SS_EN is generated by the flip-flop 740 using ddp_delay_b as the clock. ddp_delay is generated by adding, e.g., ˜500 ps delay to ddp. ddp_delay_b is an inverted version of ddp_delay (“_b” denotes bar or inverse).

The comparator 710 is a high-speed, high-precision comparator which observes Vx during the time PS2 is on. zed_hold goes high and stays high as long as a positive pulse (zcd_det=high) is detected within the comparator window, comp_window, during every clock cycle.

FIG. 8 depicts example plots consistent with implementation of the switching logic in FIG. 7, in accordance with various embodiments. The plots are of voltage versus time along a common time line with time points t0-t8, except the plots 810 and 811 are for current versus time. The plots 800 and 801 depicts two examples of Vx versus time. Generally, Vx will alternate between a peak and a valley in each clock cycle as the power switches are alternately turned on and off. For example, the plot 800 has a peak 800p and a valley 800v, and the plot 801 has a peak 801p and a valley 801v. The plot 801 remains under 0 V even at its peak 801p. In contrast, the plot 800 exceeds 0 V at its peak 800p, from t5-t8. Vx>0 V in this time range.

The plots 810 and 811 depicts inductor current I_L corresponding to the plots 800 and 801, respectively. Inductor current will generally be inverse in magnitude to Vx. The plot 811 has a peak 811p and a valley 811v, but remains above 0 V. The plot 810 has a peak 810p and a valley 810v, where the valley is below 0 A. The plots 810 falls below 0 A, representing a negative current, from t5-t8.

The plot 820 depicts dp and dn, as discussed in connection with FIG. 3, which can be synchronized with the PWM signal. Dp and dn increase from low to high at to and from high to low at t4.

The plot 830 depicts ddp, a version of dp which is delayed by tdp. ddp transitions from low to high at t3 and from high to low at t7.

The plot 840 depicts ddn, a version of dn which is delayed by tdn. ddn transitions from low to high at t2 and from high to low at t6.

The plot 850 represents a value cn.

The plot 860 represents comp_window, which is a time in which a comparison can be made between Vx and Vxref, as discussed. comp_window goes from low to high at t1 and from high at low at t7.

The plot 870 represents zcd_det, which is the output of the comparator 710 in FIG. 7. zcd_det goes high from t5-t7, consistent with Vx>0 V at t5-t8 and comp_window going high to low at t7.

When ddn goes low, the low-side transistor, PS2, is turned off completely and Vx is monitored. Vgp is driven low to turn on PS1 when Vx goes high. In particular, Vgp is driven low when ddp goes low. Thus, if tdp is set to 0 or a very low value, PS1 turns on as soon as PS2 is switched off, and hard switching is enabled. It tdp is set to a relatively large value, Vx will continue to be monitored until ddp goes low. If Vs rises and goes high, e.g., above 0 V, because of a negative inductor current within tdp, Vgp is driven low even before ddp goes low.

FIG. 9A depicts an example implementation of the comparator 710 of FIG. 7, in accordance with various embodiments. The comparator includes an input stage 910, a first stage 920, a second stage 940, an output stage 960 and a multiplexer 990 (mux). The comparator includes n-type MOSFETs denoted by MN and p-type MOSFETs denoted by MP. A power rail 935 provides power to the comparator.

The input stage 910 includes a current mirror comprising parallel current paths 911 and 912 coupled to a grounding transistor MN6. The current path 911 includes transistors MP8 and MN8 in series, where the control gate of MN8 receives a signal comp_out1. MP8 is a diode-connected transistor since its drain and gate are connected together. The current path 912 includes transistors MP9 and MN7 in series, where the control gate of MN7 receives comp_out1_b, the inverse of comp_out1. The input stage provides a current on a path 913 to the control gate of a clamping transistor Mclamp in the first stage 920. Mclamp is provided to help reduce phase delay. comp_out1_b is generated by the first stage at the node 923 and comp_out1 is generated by the first stage at the node 924.

The first stage 920 includes a current mirror comprising parallel current paths 921 and 922. The current path 921 includes transistors MP1, MP3 and MN2 in series. The current path 922 includes transistors MP2, MP4 and MN1 in series. The control gates of MP1 and MP2 receive a voltage vbias, and the control gates of MP3 and MP4 receive a voltage vcascbias. The drain of MN2 is coupled to a node 923 which outputs comp_out1_b, and the drain of MN1 is coupled to a node 924 which outputs comp_out1. A source of MN2 is coupled to ground. One source/drain side 925 of Mclamp is coupled by a switch S1 to one side 926 of a capacitor C1, which in turn has another side 927 coupled to an output 991 of the multiplexer 990. The other source/drain side 928 of Mclamp is coupled by a switch S2 to one side 929 of a capacitor C2, which in turn has another side 930 coupled to ground. The control gate of MN2 is at a voltage Vsh2 according to the side 926 of the capacitor C1, and the control gate of MN1 is at a voltage Vsh1 according to the side 929 of the capacitor C2.

The multiplexer receives inputs of Vx and Vxref and passes one of these inputs on the multiplexer output 991 to the side 927 of the capacitor C1 and to the source of MN1.

The second stage 940 includes a current mirror comprising parallel current paths 941 and 942 coupled to a grounding transistor MN5. The current path 941 includes transistors MP5 and MN4 in series, and the current path 942 includes transistors MP6 and MN3 in series. MP5 is a diode-connected transistor. The control gate of MN4 receives comp_out1 and the control gate of MN3 receives comp_out1_b. The second stage provides a current on a path 943 to an inverter 961 and to the drain of MP7. A control gate of MP7 is coupled to a path 944 which in turn is coupled to control gates of the grounding transistors MN5 and MN6.

The output stage 960 includes a number of logic gates and a delay circuit 964. The inverter 961 receives comp_out2 and inverts it to provide comp_out2_B to a first input of a NOR gate 962. A second input of the NOR gate receives zcd_window_b. An output of the NOR gate is provided to a first input of an AND gate 965 via a delay circuit 964 which may impose a delay of 100 ps, for example, as part of a glitch filter 963. The output of the NOR gate is also provided without delay to a second input of the AND gate 965. The glitch filter is used to filter out glitches (e.g., undesired, and often abrupt changes in a signal) due to noise on Vx, such as due to coupling from other stages of the comparator.

The output of the AND gate 965 is provided to an inverter 966, and an output of the inverter 966 is provided to another inverter 967 whose output is comp_out. An AND gate 968 receives the output of the inverter 966 and comp_window and provides a corresponding output voltage on the path 944 such as to disable the input stage 910 and the second stage 940 when they are not in use.

In further detail, in the first stage, when PS1 is on, MN1 and MN2 are diode-connected and the capacitors C1 and C2 are auto-zeroed by feeding in Vxref from the multiplexer. At this time, the second stage is off to reduce quiescent current, Iq. The final output of the comparator is gated by zcd_window at the NOR gate 962.

In the second stage, Vx is fed into the first stage by the multiplexer when comp_window does high once PS2 turns on. For negative values of Vx, comp_out1 goes low and the second stage consumes Iq. MN4 mirrors the current on MN1 when Vx crosses above 0 V (Vxref). The second stage can be disabled during the auto-zero operation at the first stage to save Iq. During the comparison of Vx to Vxref, whenever Vx is negative, comp_out1 will be lower than Vsh1, thereby reducing the current through MN4 and hence the overall Iq of the second stage. As soon as Vx become positive, comp_out1 rises above Vsh1 followed by comp_out2 going high and comp_out going high. Once a positive voltage (Vx) is detected within the comparison phase of a clock cycle, the output gets locked and the second stage is disabled again to reduce Iq.

The comparator 710 is a fully differential auto-zeroed comparator with precision sensing of a zero-voltage crossover by Vx. The switches S1, S2 and S4 are closed (conductive) during the PS2 off phase. Soon after PS2 is turned on, S1 and S2 are opened (non-conductive) followed by switching of the multiplexer output from Vxref=0 V to Vx. A positive inductor current generates a negative Vx thereby pulling comp_out2 low. As soon as the current goes negative, Vx goes positive and comp_out2 goes high.

The current consumption is also defined better and the power-supply rejection ratio (PSRR) is improved with a fully differential architecture.

Configuration bits can be used to enable resistance modulation to achieve hysteresis while entering soft switching and discontinuous conduction modes (DCMs). For example, if it is desired to soft switch load currents below 0.9 A, the circuit could be configured to enable soft switching below, e.g., 0.85 A. But to ensure stability, a hysteresis of 0.1 A can be added, thereby enabling soft switching only below 0.75 A.

Routing of Vx and Vxref should be symmetric and low resistance (e.g., <10 Ohms). Parasitic metal resistance does not significantly affect the voltage drop across the multiplexer MOSFETs when targeting single digit mV accuracy.

A Delta Vgs clamp can be used to improve the temperature compensation of the trip point. The delta Vgs is designed to be larger than the worst-case random offset between MN3 and MN4.

Additionally, both the clamping amplifier and the second state comparator amplifier are off during the auto-zeroing operation. During the sense operation, negative Vx values bring down comp_out1 node, reducing the Iq through these amplifiers. They consume current close to the trip point and are turned off as soon as the comparator trips.

Another benefit is that ripple current is reduced when transitioning from hard switching to soft switching. A hysteresis can be used to avoid continuous toggling between the two switching modes.

The switching control logic can alter the ddp delay, effectively altering the turn on time of PS1. In other words, the duty cycle of the PWM signal is altered through the switching control logic. With tdp limited to a maximum of 1 ns, for example, the gain of the control is also limited, but is still large enough to create small signal oscillations at the output when the loop control of the VR is in contention with the switching control. This can be resolved by compensating the switching control loop or ensuring that the switching control loop is sufficiently slow. Stability can be ensured by providing a slow transition from hard to soft switching.

The input/first stage 920 of the comparator 710 has a ‘fully differential’ (differential input, differential output) architecture. The second stage 940 has a ‘differential to single ended’ architecture. The input stage 910 is a separate amplifier that is used to achieve active clamping of the outputs of the input/first stage. The input stage 910 helps in speeding up the response time of the comparator by trying to reduce the differential swing at the outputs of the first stage 920. For example, in the absence of the input stage 910, when Vx is a large negative number, comp_out1 goes close to 0 and comp_out1_b goes close to Vccags. When Vx moves towards 0, comp_out1 will swing up and comp_out1_b will swing down, approaching towards each other. This means the difference (comp_out1_b-comp_out1) is swinging all the way from Vccags to 0 as Vx is changing. With the input stage 910 included, the negative feedback loop tries to regulate the Vds across Mclamp to be limited to a set value (AVgs) decided by the skew in the sizing of the input pair transistors (MN7 and MN8) of the input stage 910. This limits the max swing (comp_out1_b comp_out1) value to AVgs. As soon as (comp_out1_b-comp_out1) swings from AVgs to 0 and crosses zero as Vx changes from a negative value to 0, the output of the second stage 940, comp_out2 goes high and we detect the zero cross over. The output stage 960 locks this information through positive feedback, i.e., once comp_out goes high, it stays high until the zcd_window goes low.

FIG. 9B depicts an example implementation of the multiplexer 990 of FIG. 9A, in accordance with various embodiments. The multiplexer is represented by switches S3 and S4 in FIG. 9A for simplicity. In the example implementation, the multiplexer includes transistors T1-T4 such as n-type MOSFETs in series between a node 992 which receives Vx and a node 993 which receives Vxref. The control gates of T1 and T4 are controlled by a voltage Vccdrvn on a path 994. The control gates of T2 and T3 receive the signals comp_window and comp_window_b, respectively.

T1 and T2 can be adjustable for resistance modulation for both hysteresis and fine tuning the capacitor.

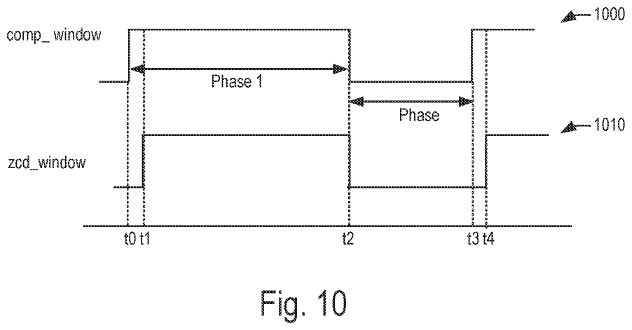

FIG. 10 depicts example plots consistent with the implementation of the comparator 710 in FIG. 9A, in accordance with various embodiments. Plot 1000 depicts comp_window and plot 1010 depicts zcd_window. The time from t0-t2 represent phase 1 operations which involve the first stage of the comparator, and the time from t2-t4 represents phase 2 operations which involve the second stage of the comparator.

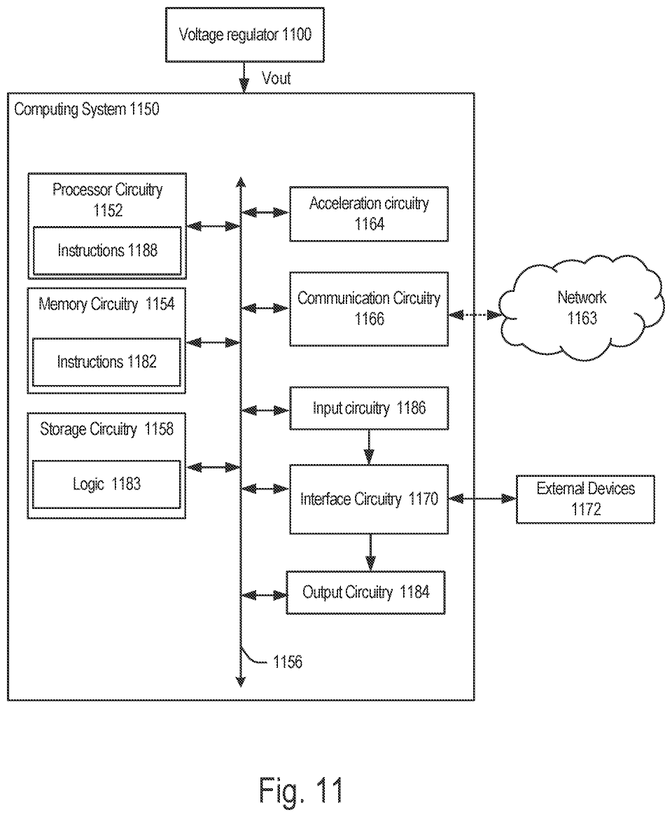

FIG. 11 illustrates an example of components that may be present in a computing system 1150 for implementing the techniques (e.g., operations, processes, methods, and methodologies) described herein.

The voltage regulator 1100 may represent the switching power converter 100 of FIG. 1, for example.

The computing system 1150 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 1150, or as components otherwise incorporated within a chassis of a larger system. For one embodiment, at least one processor 1152 may be packaged together with computational logic 1282 and configured to practice aspects of various example embodiments described herein to form a System in Package (SiP) or a System on Chip (SoC).

The voltage regulator 1200 may provide a voltage Vout to one or more of the components of the computing system 1250. The memory circuitry 1254 may store instructions and the processor circuitry 1252 may execute the instructions to perform the functions described herein.

The system 1150 includes processor circuitry in the form of one or more processors 1152. The processor circuitry 1152 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 1152 may include one or more hardware accelerators (e.g., same or similar to acceleration circuitry 1164), which may be microprocessors, programmable processing devices (e.g., FPGA, ASIC, etc.), or the like. The one or more accelerators may include, for example, computer vision and/or deep learning accelerators. In some implementations, the processor circuitry 1152 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 1152 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 1152 may be coupled with or may include memory/storage and may be configured to execute instructions stored in the memory/storage to enable various applications or operating systems to run on the platform 1150. The processors (or cores) 1752 is configured to operate application software to provide a specific service to a user of the platform 1750. In some embodiments, the processor(s) 1752 may be a special-purpose processor(s)/controller(s) configured (or configurable) to operate according to the various embodiments herein.

As examples, the processor(s) 1152 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 1152 may be a part of a system on a chip (SoC), System-in-Package (SiP), a multi-chip package (MCP), and/or the like, in which the processor(s) 1152 and other components are formed into a single integrated circuit, or a single package, such as the Edison™ or Galileo™ SoC boards from Intel® Corporation. Other examples of the processor(s) 1152 are mentioned elsewhere in the present disclosure.

The system 1150 may include or be coupled to acceleration circuitry 1164, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 1164 may comprise logic blocks or logic fabric and other interconnected resources that may be programmed (configured) to perform various functions, such as the procedures, methods, functions, etc. of the various embodiments discussed herein. In such implementations, the acceleration circuitry 1164 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 1152 and/or acceleration circuitry 1164 may include hardware elements specifically tailored for machine learning and/or artificial intelligence (AI) functionality. In these implementations, the processor circuitry 1152 and/or acceleration circuitry 1764 may be, or may include, an AI engine chip that can run many different kinds of AI instruction sets once loaded with the appropriate weightings and training code. Additionally or alternatively, the processor circuitry 1152 and/or acceleration circuitry 1164 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPS™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 1152 and/or acceleration circuitry 1764 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin provided by Huawei®, and/or the like. In some hardware-based implementations, individual subsystems of system 1150 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 1150 also includes system memory 1154. Any number of memory devices may be used to provide for a given amount of system memory. As examples, the memory 1154 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 1154 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 1154 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 1158 provides persistent storage of information such as data, applications, operating systems and so forth. In an example, the storage 1158 may be implemented via a solid-state disk drive (SSDD) and/or high-speed electrically erasable memory (commonly referred to as “flash memory”). Other devices that may be used for the storage 1158 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 1154 and/or storage circuitry 1158 may also incorporate three-dimensional (3D) cross-point (XPOINT) memories from Intel® and Micron®.

The memory circuitry 1154 and/or storage circuitry 1158 is/are configured to store computational logic 1183 in the form of software, firmware, microcode, or hardware-level instructions to implement the techniques described herein. The computational logic 1183 may be employed to store working copies and/or permanent copies of programming instructions, or data to create the programming instructions, for the operation of various components of system 1150 (e.g., drivers, libraries, application programming interfaces (APIs), etc.), an operating system of system 1150, one or more applications, and/or for carrying out the embodiments discussed herein. The computational logic 1183 may be stored or loaded into memory circuitry 1154 as instructions 1182, or data to create the instructions 1182, which are then accessed for execution by the processor circuitry 1152 to carry out the functions described herein. The processor circuitry 1152 and/or the acceleration circuitry 1164 accesses the memory circuitry 1154 and/or the storage circuitry 1158 over the interconnect (IX) 1156. The instructions 1182 direct the processor circuitry 1152 to perform a specific sequence or flow of actions, for example, as described with respect to flowchart(s) and block diagram(s) of operations and functionality depicted previously. The various elements may be implemented by assembler instructions supported by processor circuitry 1152 or high-level languages that may be compiled into instructions 1188, or data to create the instructions 1188, to be executed by the processor circuitry 1152. The permanent copy of the programming instructions may be placed into persistent storage devices of storage circuitry 1158 in the factory or in the field through, for example, a distribution medium (not shown), through a communication interface (e.g., from a distribution server (not shown)), over-the-air (OTA), or any combination thereof.

The IX 1156 couples the processor 1152 to communication circuitry 1166 for communications with other devices, such as a remote server (not shown) and the like. The communication circuitry 1166 is a hardware element, or collection of hardware elements, used to communicate over one or more networks 1163 and/or with other devices. In one example, communication circuitry 1166 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 1166 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 1156 also couples the processor 1152 to interface circuitry 1170 that is used to connect system 1150 with one or more external devices 1172. The external devices 1172 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 1150, which are referred to as input circuitry 1186 and output circuitry 1184. The input circuitry 1186 and output circuitry 1184 include one or more user interfaces designed to enable user interaction with the platform 1150 and/or peripheral component interfaces designed to enable peripheral component interaction with the platform 1150. Input circuitry 1186 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 1184 may be included to show information or otherwise convey information, such as sensor readings, actuator position(s), or other like information. Data and/or graphics may be displayed on one or more user interface components of the output circuitry 1184. Output circuitry 1184 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 1150. The output circuitry 1184 may also include speakers and/or other audio emitting devices, printer(s), and/or the like. Additionally or alternatively, sensor(s) may be used as the input circuitry 1184 (e.g., an image capture device, motion capture device, or the like) and one or more actuators may be used as the output device circuitry 1184 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 1150 may communicate over the IX 1156. The IX 1156 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 1156 may be a proprietary bus, for example, used in a SoC based system.

The number, capability, and/or capacity of the elements of system 1150 may vary, depending on whether computing system 1150 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 1150 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: a power train comprising first and second power switches; an inductor coupled to an output node of the power train; a comparator having a first input coupled to the output node and a second input coupled to a reference voltage; a counter coupled to an output of the comparator; and a delay circuit responsive to the counter.

Example 2 includes the apparatus of Example 1, wherein the reference voltage is a ground voltage, and the comparator is to determine when the output voltage exceeds the ground voltage.

Example 3 includes the apparatus of Example 1 or 2, wherein the comparator is to compare the voltage of the output node to the reference voltage in clock cycles of a clock signal, and output a first value (zcd_det=1) for each of the clock cycles in which the output voltage is greater than the reference voltage and output a second value (0) for each of the clock cycles in which the output voltage is less than the reference voltage.

Example 4 includes the apparatus of Example 3, wherein, in response to the counter determining that the first value is output from the comparator in N consecutive clock cycles of the clock signal, the delay circuit is to start to increase a time interval between application of a turn off voltage to the second power switch and application of a turn on voltage to the first power switch.

Example 5 includes the apparatus of Example 4, wherein the increase of the time interval comprises multiple steps, and each step of the multiple steps comprises multiple clock cycles.

Example 6 includes the apparatus of Example 4 or 5, wherein the time interval is increased by at least a factor of ten, from a level associated with hard switching of the first power switch to a level associated with soft switching of the first power switch.

Example 7 includes the apparatus of any one of Examples 4-6, wherein after the increase of the time interval, the delay circuit is to decrease the time interval when the comparator outputs the second value.

Example 8 includes the apparatus of any one of Examples 1-7, further comprising a voltage regulator which includes the power train, the inductor, the comparator, the counter and the delay circuit, wherein the voltage regulator is provided in at least one of an integrated circuit, a System on Chip, a System in Package or a computing device.

Example 9 includes an apparatus, comprising: a memory to store instructions; and a processor to execute the instructions to: for each clock cycle of a plurality of clock cycles of a clock signal, compare a voltage of an output node of a power train to a ground voltage as the output voltage alternates between a peak and a valley, wherein the power train comprises a p-type transistor in series with an n-type transistor; and in response to the comparing indicating the voltage of the output node is greater than the ground voltage in each clock cycle of a number N of consecutive clock cycles of the plurality of clock cycles, start to transition a switching signal of the p-type transistor from hard switching to soft switching, wherein compared to the hard switching, the soft switching has a larger time period between application of a turn off voltage to the n-type transistor and application of a turn on voltage to the p-type transistor.

Example 10 includes the apparatus of Example 9, wherein the output node of the power train is coupled to a first end of an inductor, and the processor is to execute the instructions to: compare a voltage of a second end of the inductor to a requested output voltage; and adjust a duty cycle of the switching signal of the p-type transistor based on the comparing of the voltage of the second end of the inductor to the requested output voltage.

Example 11 includes the apparatus of Example 9 or 10, wherein the processor is to execute the instructions to increment a count for each consecutive clock cycle of the plurality of clock cycles in which the comparing indicates the voltage of the output node is greater than the ground voltage, and determine when the count reaches the number N.

Example 12 includes the apparatus of any one of Examples 9-11, wherein the processor is to execute the instructions to perform soft switching for the n-type transistor regardless of whether soft switching is performed for the p-type transistor.

Example 13 includes the apparatus of any one of Examples 9-12, wherein to transition the switching signal of the p-type transistor from hard switching to soft switching, the processor is to execute the instructions to increment the time period after every M clock cycles of the clock signal, wherein M<N, until the time period reaches a maximum allowable level.

Example 14 includes the apparatus of any one of Examples 9-13, wherein after the start of the transition, the processor is to execute the instructions to terminate the transition of the switching signal from hard switching to soft switching and return the switching signal to hard switching in response to the comparing indicating the voltage of the output node is no longer greater than the ground voltage.

Example 15 includes the apparatus of any one of Examples 9-14, wherein after completion of the transition, the processor is to execute the instructions to return the switching signal to hard switching in response to the comparing indicating the voltage of the output node is no longer greater than the ground voltage, and the return of the switching signal to hard switching is faster than the transition to soft switching.

Example 16 includes a comparator, comprising: a multiplexer having inputs coupled to an output voltage (Vx) of a power train and a reference voltage (Vxref), wherein the power train comprises a p-type transistor in a series with an n-type transistor; a first stage coupled to an output of the multiplexer, wherein the first stage is to output a first value (comp_out1) indicating whether the output voltage exceeds the reference voltage when the multiplexer passes the output voltage; a second stage coupled to the first stage and comprising a current mirror, wherein a control gate of a transistor in a first path of the current mirror is receive the first value and a second path of the current mirror is to output a second value (comp_out2) indicating whether the output voltage exceeds the reference voltage; and an output stage coupled to the second stage, wherein the output stage is to output a third value (comp_out) based on the second value indicating whether the output voltage exceeds the reference voltage during a time window in a clock cycle.

Example 17 includes the comparator of Example 16, wherein the first stage comprises a clamping diode between first and second paths of a current mirror of the first stage.

Example 18 includes the comparator of Example 16 or 17, wherein the first stage comprises capacitors which are auto-zeroed when the multiplexer passes the reference voltage.

Example 19 includes the comparator of any one of Examples 16-18, wherein the second stage is disabled when the capacitors are auto-zeroed.

Example 20 includes the comparator of Example 18 or 19, wherein the n-type transistor is on when the multiplexer passes the output voltage and the p-type transistor is on when the multiplexer passes the reference voltage.

Example 21 includes a method, comprising: for each clock cycle of a plurality of clock cycles of a clock signal, comparing a voltage of an output node of a power train to a ground voltage as the output voltage alternates between a peak and a valley, wherein the power train comprises a p-type transistor in series with an n-type transistor; and in response to the comparing indicating the voltage of the output node is greater than the ground voltage in each clock cycle of a number N of consecutive clock cycles of the plurality of clock cycles, start to transition a switching signal of the p-type transistor from hard switching to soft switching, wherein compared to the hard switching, the soft switching has a larger time period between application of a turn off voltage to the n-type transistor and application of a turn on voltage to the p-type transistor.

Example 22 includes the method of Example 21, wherein the output node of the power train is coupled to a first end of an inductor, and the processor is to execute the instructions to: compare a voltage of a second end of the inductor to a requested output voltage; and adjust a duty cycle of the switching signal of the p-type transistor based on the comparing of the voltage of the second end of the inductor to the requested output voltage.

Example 23 includes the method of Example 21 or 22, wherein the processor is to execute the instructions to increment a count for each consecutive clock cycle of the plurality of clock cycles in which the comparing indicates the voltage of the output node is greater than the ground voltage, and determine when the count reaches the number N.

Example 24 includes the method of any one of Examples 21-23, wherein the processor is to execute the instructions to perform soft switching for the n-type transistor regardless of whether soft switching is performed for the p-type transistor.

Example 25 includes the method of any one of Examples 21-24, wherein to transition the switching signal of the p-type transistor from hard switching to soft switching, the processor is to execute the instructions to increment the time period after every M clock cycles of the clock signal, wherein M<N, until the time period reaches a maximum allowable level.

Example 26 includes the method of any one of Examples 21-25, wherein after the start of the transition, the processor is to execute the instructions to terminate the transition of the switching signal from hard switching to soft switching and return the switching signal to hard switching in response to the comparing indicating the voltage of the output node is no longer greater than the ground voltage.

Example 27 includes the method of any one of Examples 21-26, wherein after completion of the transition, the processor is to execute the instructions to return the switching signal to hard switching in response to the comparing indicating the voltage of the output node is no longer greater than the ground voltage, and the return of the switching signal to hard switching is faster than the transition to soft switching.

Example 28 includes a non-transitory machine-readable storage including machine-readable instructions that, when executed, cause a processor or other circuit or computing device to implement the method of any one of Examples 21-27.

Example 29 includes an apparatus comprising means to perform the method in any one of Examples 21-27.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a power train comprising first and second power switches;
an inductor coupled to an output node of the power train;
a comparator having a first input coupled to the output node and a second input coupled to a reference voltage;
a counter coupled to an output of the comparator; and
a delay circuit responsive to the counter.

2. The apparatus of claim 1, wherein the reference voltage is a ground voltage, and the comparator is to determine when the output voltage exceeds the ground voltage.

3. The apparatus of claim 1, wherein the comparator is to compare the voltage of the output node to the reference voltage in clock cycles of a clock signal, and output a first value for each of the clock cycles in which the output voltage is greater than the reference voltage and output a second value for each of the clock cycles in which the output voltage is less than the reference voltage.

4. The apparatus of claim 3, wherein, in response to the counter determining that the first value is output from the comparator in N consecutive clock cycles of the clock signal, the delay circuit is to start to increase a time interval between application of a turn off voltage to the second power switch and application of a turn on voltage to the first power switch.

5. The apparatus of claim 4, wherein the increase of the time interval comprises multiple steps, and each step of the multiple steps comprises multiple clock cycles.

6. The apparatus of claim 4, wherein the time interval is increased by at least a factor of ten, from a level associated with hard switching of the first power switch to a level associated with soft switching of the first power switch.

7. The apparatus of claim 4, wherein after the increase of the time interval, the delay circuit is to decrease the time interval when the comparator outputs the second value.

8. The apparatus of claim 1, further comprising a voltage regulator which includes the power train, the inductor, the comparator, the counter and the delay circuit, wherein the voltage regulator is provided in at least one of an integrated circuit, a System on Chip, a System in Package or a computing device.

9. An apparatus, comprising:
a memory to store instructions; and
a processor to execute the instructions to:
for each clock cycle of a plurality of clock cycles of a clock signal, compare a voltage of an output node of a power train to a ground voltage as the output voltage alternates between a peak and a valley, wherein the power train comprises a p-type transistor in series with an n-type transistor; and
in response to the comparing indicating the voltage of the output node is greater than the ground voltage in each clock cycle of a number N of consecutive clock cycles of the plurality of clock cycles, start to transition a switching signal of the p-type transistor from hard switching to soft switching, wherein compared to the hard switching, the soft switching has a larger time period between application of a turn off voltage to the n-type transistor and application of a turn on voltage to the p-type transistor.

10. The apparatus of claim 9, wherein the output node of the power train is coupled to a first end of an inductor, and the processor is to execute the instructions to:
compare a voltage of a second end of the inductor to a requested output voltage; and
adjust a duty cycle of the switching signal of the p-type transistor based on the comparing of the voltage of the second end of the inductor to the requested output voltage.

11. The apparatus of claim 9, wherein the processor is to execute the instructions to increment a count for each consecutive clock cycle of the plurality of clock cycles in which the comparing indicates the voltage of the output node is greater than the ground voltage, and determine when the count reaches the number N.

12. The apparatus of claim 9, wherein the processor is to execute the instructions to perform soft switching for the n-type transistor regardless of whether soft switching is performed for the p-type transistor.

13. The apparatus of claim 9, wherein to transition the switching signal of the p-type transistor from hard switching to soft switching, the processor is to execute the instructions to increment the time period after every M clock cycles of the clock signal, wherein M<N, until the time period reaches a maximum allowable level.

14. The apparatus of claim 9, wherein after the start of the transition, the processor is to execute the instructions to terminate the transition of the switching signal from hard switching to soft switching and return the switching signal to hard switching in response to the comparing indicating the voltage of the output node is no longer greater than the ground voltage.

15. The apparatus of claim 9, wherein after completion of the transition, the processor is to execute the instructions to return the switching signal to hard switching in response to the comparing indicating the voltage of the output node is no longer greater than the ground voltage, and the return of the switching signal to hard switching is faster than the transition to soft switching.

16. A comparator, comprising:
a multiplexer having inputs coupled to an output voltage of a power train and a reference voltage, wherein the power train comprises a p-type transistor in a series with an n-type transistor;
a first stage coupled to an output of the multiplexer, wherein the first stage is to output a first value indicating whether the output voltage exceeds the reference voltage when the multiplexer passes the output voltage;
a second stage coupled to the first stage and comprising a current mirror, wherein a control gate of a transistor in a first path of the current mirror is receive the first value and a second path of the current mirror is to output a second value indicating whether the output voltage exceeds the reference voltage; and
an output stage coupled to the second stage, wherein the output stage is to output a third value based on the second value indicating whether the output voltage exceeds the reference voltage during a time window in a clock cycle.

17. The comparator of claim 16, wherein the first stage comprises a clamping diode between first and second paths of a current mirror of the first stage.

18. The comparator of claim 16, wherein the first stage comprises capacitors which are auto-zeroed when the multiplexer passes the reference voltage.

19. The comparator of claim 18, wherein the second stage is disabled when the capacitors are auto-zeroed.

20. The comparator of claim 18, wherein the n-type transistor is on when the multiplexer passes the output voltage and the p-type transistor is on when the multiplexer passes the reference voltage.
